(19) United States
(12) Patent Application Publication
(10) Pub. No.: US 2016/0046100 A1
(43) Pub. Date: Feb. 18, 2016

(54) OBJECT HAVING A DUCTILE AND CORROSION RESISTANT SURFACE LAYER

(71) Applicants: Bo Gillesberg, Augustenborg (DK); Soeren Ericksen, Roskilde (DK)

(72) Inventors: Bo Gillesberg, Augustenborg (DK); Soeren Ericksen, Roskilde (DK)

(21) Appl. No.: 14/721,817

(22) Filed: May 26, 2015

Related U.S. Application Data
(63) Continuation-in-part of application No. 12/743,877, filed on Jul. 20, 2010, now abandoned.

(51) Int. Cl. B32B 15/01; C23C 16/06

(52) U.S. Cl. CPC B32B 15/01; B32B 15/013; C23C 16/06

(57) ABSTRACT

This invention relates to an object having a corrosion resistant surface that is also sufficiently ductile to let the surface, or the whole object, be mechanically modified without creating cracks or other weaknesses undermining or damaging the corrosion resistance. The surface layer preferably contains at least 80% of a refractory metal, such as tantalum, and an alloy layer is created between a core element and the surface layer having the needed ductility and adhering abilities.

### CROSS REFERENCE TO RELATED APPLICATIONS

This application is a continuation-in-part application of U.S. patent application Ser. No. 12/743,877 filed on Jul. 20, 2010, which is the National Stage filing of PCT Application No. PCT/DK2008/000414 filed on Nov. 20, 2008, which claims priority to Danish Patent Application No. PA 2007 01652 filed Nov. 21, 2007, which are hereby incorporated by reference in their entirety.

### FIELD OF THE INVENTION

This invention relates to an object having a corrosion resistant surface that is also sufficiently ductile to let the surface, or the whole object, be mechanically modified without creating cracks or other weaknesses undermining or damaging the corrosion resistance. The surface layer preferably contains at least 80% of a refractory metal, such as tantalum, and an alloy layer is created between a core element and the surface layer having the needed ductility and adhering abilities.

### BACKGROUND

Objects which are meant to be positioned in highly corrosive environments must have an outer surface which is corrosion resistant in order to protect the object. Such a corrosion resistant outer surface may be provided by manufacturing the entire object from a corrosion resistant material. This may, however, be undesirable, e.g. due to the costs involved in manufacturing such an object, or because the corrosion resistant material may fail to meet other requirements or properties which the object has to fulfil or have, e.g. in terms of strength, magnetic properties, flexibility, durability, density, weight, thermal or electrical conductivity, workability (e.g. with respect to pressing, stamping, welding, forging, screwing, soldering or gluing), elasticity, fatigue properties, lubrication related properties, hardness, roughness, etc. Accordingly, a corrosion resistant outer surface is often provided by coating the object with a layer of corrosion resistant material, such as tantalum (Ta).

It is vital that such a surface layer is tight without pinholes creating exposed spots of the object under the coating to the highly corrosive environments, and a number of documents describes methods to apply such a pinhole free layer, such as EP0578605B1 describing a molten bath for plating with high-melting metals, in particular niobium and tantalum. The bath consists of an alkali metal fluoride melt, which contains oxide ions and ions of the metal to be precipitated. The molar ratio between the metal to be precipitated and the oxide ions, or the other cat ions in the melt, must be held within given ratios. The redox level must be held at a value which corresponds to that which is reached when the molten bath is in contact with the particular high-melting metal in the metallic form.

Another example is EP1501962B1 relating to a method for modifying a metallic surface, the method comprising chemical vapour deposition on a substrate in a chamber adapted for CVD involving at least the steps of:
subjecting the substrate to chemical vapour deposition with a flow of reactant gas comprising a metal compound to be incorporated in the metal surface; and interrupting the chemical vapour deposition by cutting off the flow of reactant

A document U.S. Pat. No. 5,087,856 describes an object having a core of stainless steel covered by a surface layer of substantially tantalum, the object being a discharge electrode for a charger having a thin wire or core made of stainless steel or electrolytically polished tungsten, and a coating provided on the thin line. To form the coating, an amorphous alloy containing tantalum, niobium, zirconium, titanium or similar element belonging to the same group on the periodic table is deposited on the thin wire by sputtering, CVD (Chemical Vapor Deposition) or similar technology. The content of tantalum in the amorphous alloy is selected to be 10% to 70%.

A content of even 70% is, however, not corrosion resistant enough for many corrosive environments, a concentration of at least 70%, or better more than 80% will often be required.

A document U.S. Pat. No. 4,786,468 describes alloys highly resistant to corrosion by concentrated acid and having excellent adhering properties when coated on stainless steel, which are formed of 60 to 90 atomic percent tantalum or tungsten, with the remainder being iron, chromium and nickel in the proportions found in stainless steel, e.g., 304L stainless steel. They may be formed in situ on the surface to be coated by sputter deposition, using a sputter target which is part tungsten or tantalum, and part stainless steel.

As revealed in e.g. this document it is a known problem to adhere such a tantalum rich surface coating to especially stainless steel, especially when it also needs to be pinhole free. In a document WO 98/46809 a solution is suggested relating to electroplating with refractory metal, mainly tantalum and niobium, from molten salts and can be applied in chemical, metallurgical, pharmaceutical, medical industries, turbine manufacture, air- and spacecraft, and other areas of engineering, in creation of corrosion-resistant and barrier coatings. The essence of the invention is that when the article to be coated is immersed into a molten electrolyte containing fluorides of both refractory and alkali metal and a eutectic melt of sodium, potassium and caesium chlorides, the article is warmed up to the working temperature of the electrolyte of 700-770° C. whereupon direct or reverse electric current is passed through the electrolyte, the current parameters being adjusted so that the quantity of electricity in the anodic Qa, and cathodic Qc, parts of the electroplating cycle corresponds to the ratio O≦Qa/Qc<0.9. To improve the article quality it is desirable that the weight of the electrolyte exceeds that of the article by 5 times or more. The technical result attained is the production of uniform-thickness, high quality tantalum or niobium coatings on articles for industrial applications made of conventional materials. Open porosity of the resulting coatings is not higher than 0. 001%, adhesion to the substrate is as high as 8 kg/mm.

Some coated objects are subdued to a mechanical modification after applying the coating, this could e.g. because it is desired to manufacture an object which comprises grooves in the surface to be used as flow channels in such systems as fuel cells, heat exchangers, lab on a chip or the like. The process of modifying the object, like forming the grooves in the surface, may be at the risk that the process weakens the corrosion resistant properties of the coating material in a zone where the objects are modified. The modification may also be a result of e.g. drawing objects from a larger coated preform. Objects may also, either during operational use or just simply due to the operational environments, be mechanically subdued to impacts, blows, strokes, grinding, plastic or elastic deformations, this could be tools in general, rotor blades, fans, bellows, pistons etc. Other objects may be mechanically deformed unintentionally due to influence of tools during installation. E.g. a nut may be slightly deformed when tightened with a wrench. Further parts may be exposed to rough handling (e.g. strokes by a tool to ensure right placement in a setup) that may deform the coating and substrate. In all cases, the modified, deformed, or just affected zones will represent a weak zone or point with respect to corrosion, and there is a risk that the combined object will corrode when positioned in a corrosive environment. This is very undesirable.

It is known to apply such a layer in order to create some mechanical properties besides the corrosion properties, such as giving hard wear resistant surfaces. This is described in e.g. U.S. Pat. No. 4,341,834, teaching how to create a cutting tool or a wear-resistant mechanical part that comprises: a substrate with or without an inner coating layer of TiC, TiN or TiCN; an intermediate layer of a titanium oxycarbide formed on the surface of the substrate or the inner coating layer by carrying out a reaction thereon at a temperature of 800° to 1,200° C. of a halide of titanium, hydrogen, and carbon monoxide or carbon dioxide or a mixture thereof; and an outer coating layer of aluminium oxide formed on the outer surface of the intermediate layer. The thicknesses of the inner layer, the intermediate layer, and the outer coating layer are of the order of 0.5 to 20 microns, 0.5 to 20 microns, and 0.5 to 10 microns, respectively. The substrate of a coated super-hard alloy article according to this invention comprises (1) at least one of carbides, nitrides, and carbonitrides of metals of Groups 4a, 5a, and 6a of the periodic table and (2) at least one of Fe, Ni, Co, W, Mo, and Cr. Typical metals of the above group (1) are Ti, Zr, Hf, V, Nb, Ta, Cr, Mo, and W. A super-hard alloy of this character is known and is disclosed in, for example, R. Kieffer: “Hartmetalle”, Springer-Verlag (Wien-NY), 1965. Examples of these alloys suitable for use in this invention are WC—TiC—TaC—Co alloy, WC—Co alloy, WC—TiC—Co alloy, WC—TiC—TaC—NbC—Co alloy, WC—TiC—Mo2C—Ni—Co alloy, and TiC—Mo—Ni alloy. These super-hard alloys can be produced by known processes, such as, for example, a process comprising mixing powder of starting materials, pressing the mixture into a preform and sintering the preform.

### SUMMARY

It is an object of this invention to make an object with a corrosion resistant and ductile coating, unlike e.g. the hard coating for a cutting tool described in e.g. U.S. Pat. No. 4,341,834. Material concentrations referred to herein are by weight unless otherwise indicated.

The object has to be corrosion resistant, even when subdued to a treatment that may imply plastic or elastic deformation. It is further an object of this invention to make an object having a corrosion resistant surface, where the surface of the object is subdued to some mechanical modification, or mechanically subdued to impacts, blows, strokes, grinding, plastic or elastic deformations. For example, the object may be subdued to a rolling or imprinting process forming surface structures, possibly in order to make the surface rough, thus increasing the surface area and thereby the adhesion of subsequent coating layers such as a spray coated ceramic layer.
This is achieved by making a corrosion resistant object with a ductile surface, said object comprising:
a core element being made from a first base material and having an outer surface, and,
a coating layer comprising a concentration of at least 70% of a corrosion resistant material covering at least a part of the outer surface of the core element,
   wherein an alloying zone exists between the core element and the coating layer, said alloying zone having a thickness from where the concentration of said corrosion resistant material is 90% of the concentration in the coating layer, to where the concentration of said corrosion resistant material is 10% of the concentration in the coating layer, from 0.1 micrometers to 10 micrometers.

The present invention further concerns an object having an iron containing core element with a substantially pinhole free surface coating layer having good corrosion resistance, where the surface layer preferably is tantalum or a metal having a corrosion resistance significantly larger than steel, like e.g. reactive or refractory metals or just of the same group of metals as tantalum, such metals including W, Nb, Mo, Ti, Hf, Zr. The core element itself is substantially without tantalum or the metal(s) that otherwise makes up the surface coating. The core element further preferably contains Ni at a concentration by weight not more than 50%.

It is especially an object of this invention that the iron containing core element is a steel, preferably stainless or carbon steel.

To ensure good corrosion resistance of the surface, the metallised component must have a composition (metallic purity, meaning that any content of e.g. non-metals, Oxygen, Nitrogen, Carbon and so on, is ignored) with a tantalum content of 80% or higher. With a tantalum content of 80% or more, the ability of the surface is substantially identical to that of pure tantalum.

The object of the invention is further to create an object where the surface coating is ductile and has a good adhesion. It has been experienced, that the ability to attach to an iron containing core element, is highly affected by the structure of the interface between the core element and the tantalum surface.

This is achieved by a central feature of the present invention, to provide the object with an alloying zone being between a core element and a corrosion resistant surface layer. For example, if the core element is austenitic stainless steel (like AlS 316L), especially the distribution of the concentration of the alloying elements Ni, Cr and Fe is important to the adhesion.

The interface contains tantalum at an increasing concentration from the core element to the surface layer. The transition between the tantalum surface and the interface, or alloying zone, is defined by the depth where the content of tantalum is 90% of the surface concentration. The transition from the alloying zone to the core element is defined as the depth where the tantalum concentration is 10% of the surface concentration. The alloying zone is in general from 0.1 micrometers to 10 micrometers into the object, or more preferred from 0.3 to 2.0 micrometers.

In order to ensure an alloying zone with a suitable composition, the process temperature is a critical factor when using a CVD process. At temperatures below 500° C. the diffusion speed of the alloying substances in the object in general is too low to be significant. When using temperatures of 1200° C. and above on a core of stainless steel, it has been experienced that the diffusion speed of Nickel is too high to achieve a suitable structure of the alloying substances. In the interface alloying layers are formed containing high contents of Nickel. Such alloys having high Nickel contents have proven too brittle to give a good attachment or adhesion. As a rule of thumb, to ensure a good adhesion, tantalum containing phases containing more than 20% Nickel may not exist, and the Nickel content in the alloy has to be lower than that of Iron. If the content of Nickel in the alloying zone at some spot is higher than 10 times the content of Iron, there is a risk of a poor adhesion because of the formation of tantalum/Nickel alloys. In the same manner, the Nickel content may nowhere be higher than the tantalum content. For iron based substrates with a nickel content lower than 1% (e.g. Carbon steels) good results are obtained up to a temperature of 1200° C.

It therefore is a further object of this invention to make an alloying zone between the core element and the coating, wherein the alloying zone comprises the alloying elements Ni, Fe and Ta, but where the concentration by weight of Ni is nowhere higher than 20%, more preferably less than 15%, more preferably less than 10%.

It is further an object of the present invention to introduce a method to produce such an object, the method comprising the steps of:
providing a core element (2) made from a first base material and having an outer surface,
applying a coating layer (4) of a corrosion resistant material to at least a part of the outer surface of the core element by a CVD process at a temperature between 700 and 1200° C.,
applying said coating layer at a rate that ensures the formation of an alloying zone (3) between the core element (2) and the coating layer (4) having a thickness from where the concentration of said corrosion resistant is 90% of the concentration in the coating layer, to where the concentration of said corrosion resistant material is 10% of the concentration in the coating layer, of at least 0.1 micrometers.

It is further an object of this invention, to make such a corrosion resistant object with a surface sufficiently ductile to be subdued to mechanical processing, such as plastic or elastic deformations, mechanical deformations, rolling, imprinting, drawing etc.

It is further an object of this invention to provide a method to produce an object with a corrosion resistant surface, and where the surface of the object is subdued to a mechanical modification, such as rolling, imprinting, by stroke or impact. This is achieved by providing a method comprising the steps of:
providing a core element (2) made from a first base material and having an outer surface,
applying a coating layer (4) of a corrosion resistant material to at least a part of the outer surface of the core element by a CVD process at a temperature between 700 and 1200° C.,
applying said coating layer at a rate that ensures the formation of an alloying zone (3) between the core element (2) and the coating layer (4) having a thickness from where the concentration of said corrosion resistant is 90% of the concentration in the coating layer, to where the concentration of said corrosion resistant material is 10% of the concentration in the coating layer, of at least 0.1 micrometers,
mechanically modifying the surface of the object so that the surface of the core element, the alloying zone and the coating layer are affected by the modification.

It is further an object of this invention to provide an object with a corrosion resistant surface, and where the surface of the object is subdued to a mechanical modification, such as rolling, imprinting, by stroke or impact. This is achieved by providing:
a core element being made from a first base material and having an outer surface, and,
a coating layer comprising a concentration of at least 70% of a corrosion resistant material covering at least a part of the outer surface of the core element,
   wherein an alloying zone exists between the core element and the coating layer, said alloying zone having a thickness from where the concentration of said corrosion resistant material is 90% of the concentration in the coating layer, to where the concentration of said corrosion resistant material is 10% of the concentration in the coating layer, from 0.1 micrometers to 10 micrometer, and where the surface of the object has been mechanically modified in such a manner that the surface of the core element, the alloying zone and the coating layer are affected by the modification.

### BRIEF DESCRIPTION

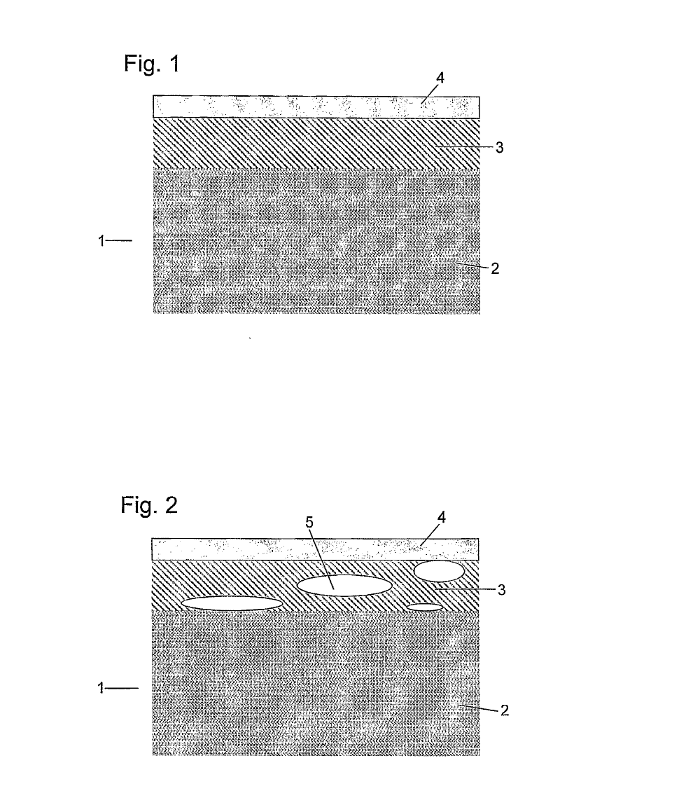

FIG. 1: is a schematic view of the invention where an alloying zone exists between the core element and the coating.

FIG. 2: is a schematic view of porosities in the alloying zone.

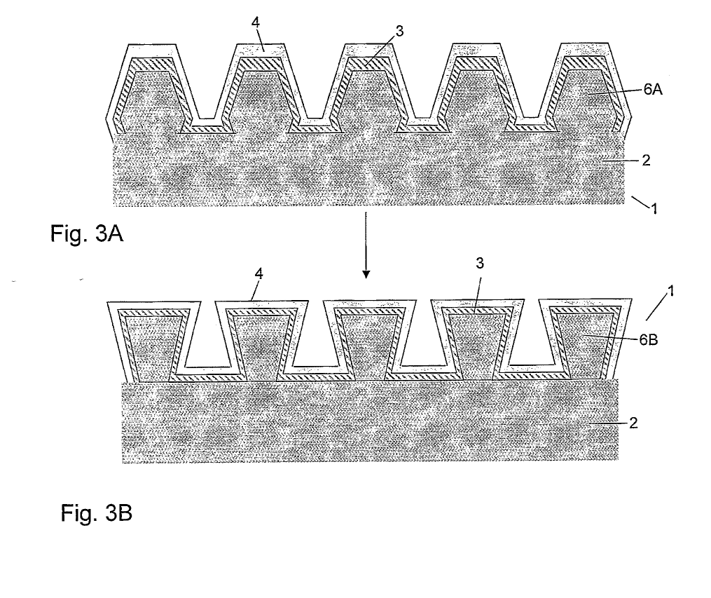

FIGS. 3 A&B: is a schematic view of a first embodiment of a surface modification of the object of the invention.

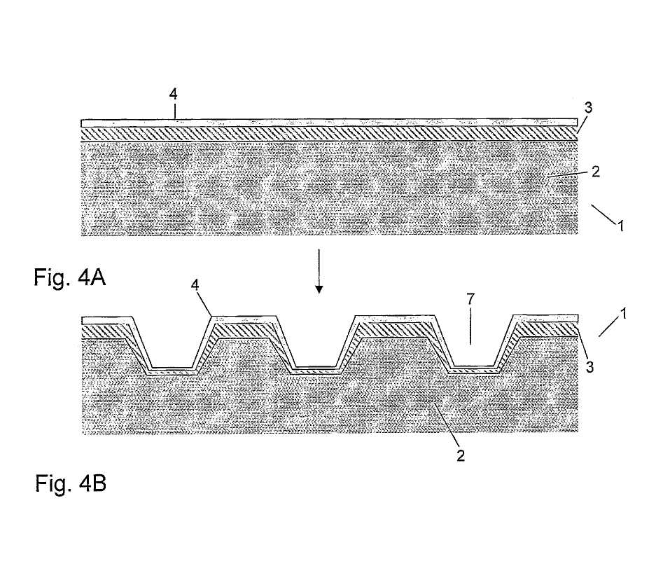

FIGS. 4 A&B: is a schematic view of a second embodiment of a surface modification of the object of the invention.

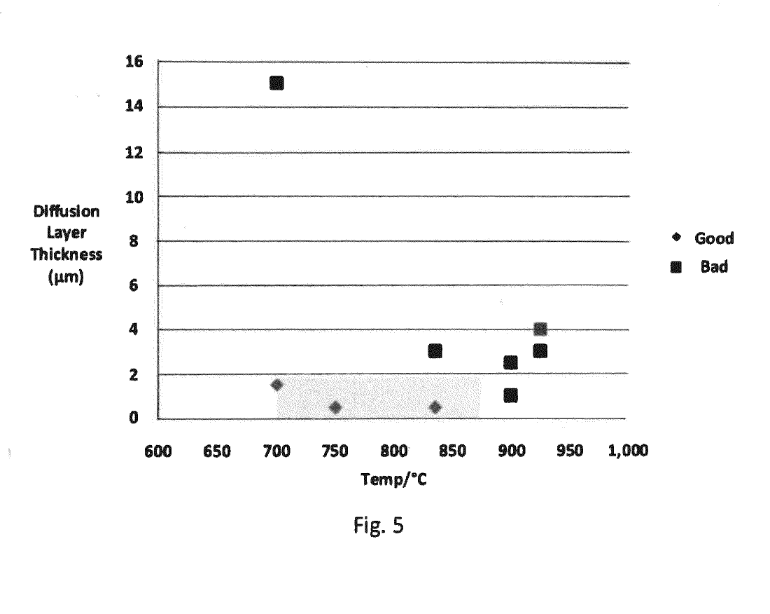

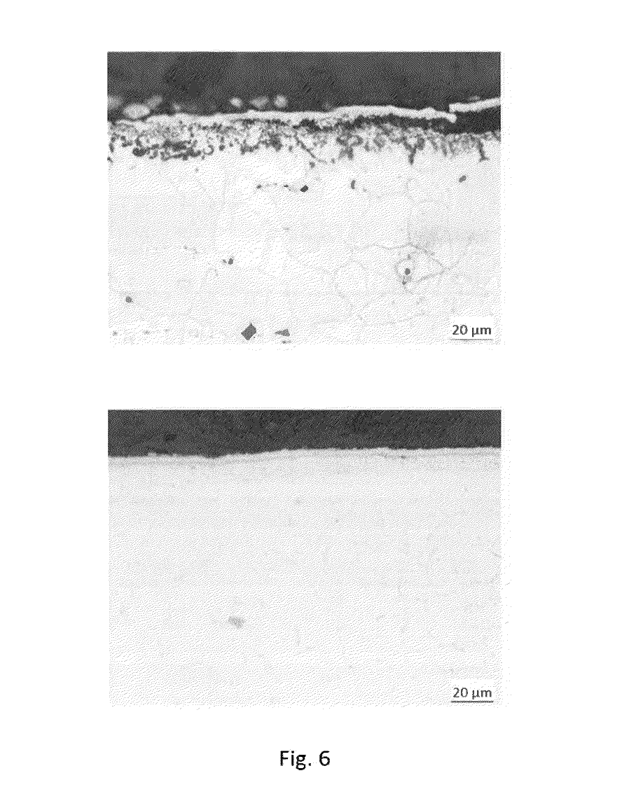

FIG. 5 shows a chart summarizing the results of various test samples shown in FIGS. 6-10.

FIG. 6 shows test samples having tantalum-coating layers deposited on substrates by a CVD process temperature of 700° C.

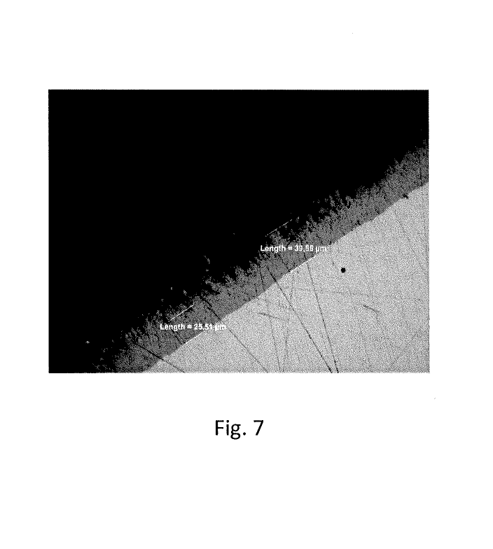

FIG. 7 shows a test sample having tantalum-coating layer deposited on a substrate by a CVD process temperature of 750° C.

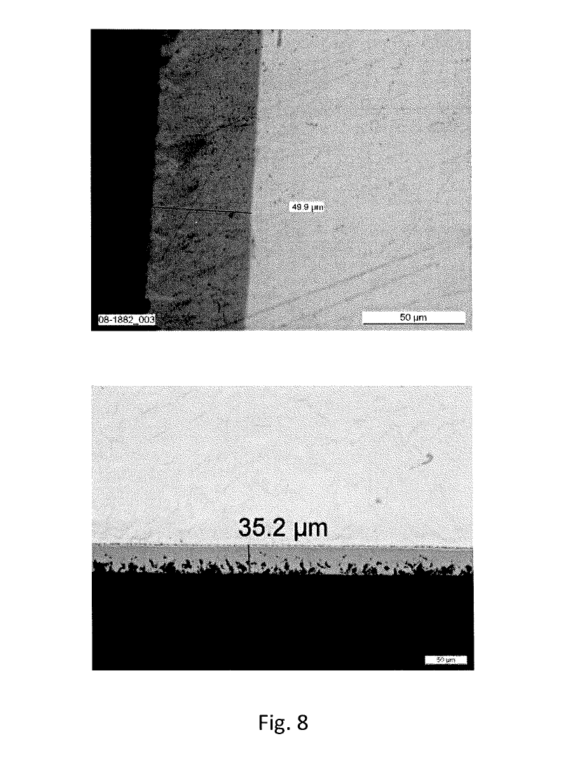

FIG. 8 shows test samples having tantalum-coating layers deposited on substrates by a CVD process temperature of 835° C.

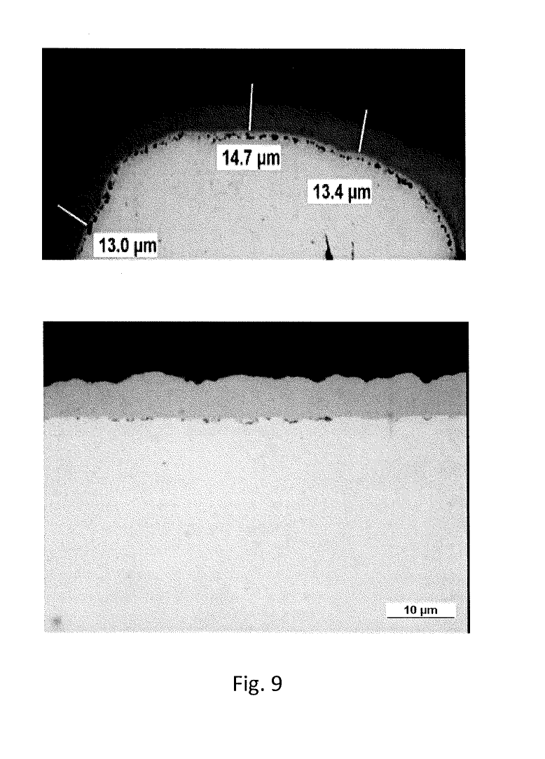

FIG. 9 shows test samples having tantalum-coating layers deposited on substrates by a CVD process temperature of 900° C.

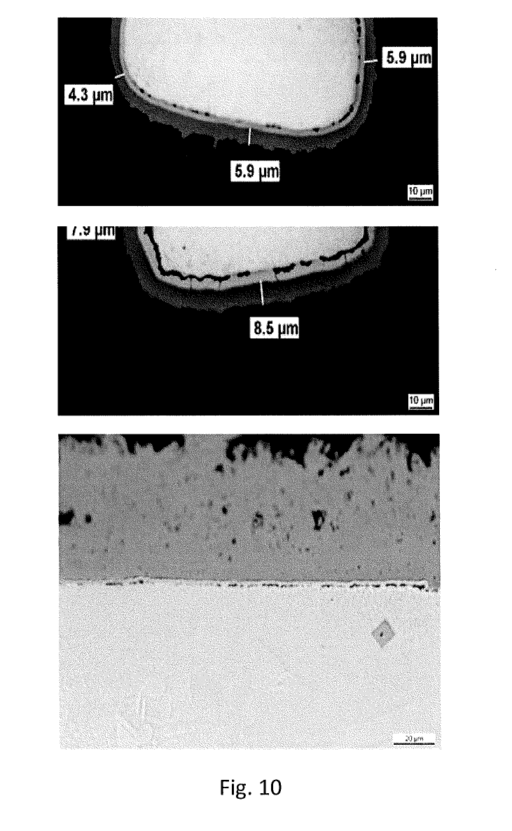

FIG. 10 shows test samples having tantalum-coating layers deposited on substrates by a CVD process temperature of 925° C.

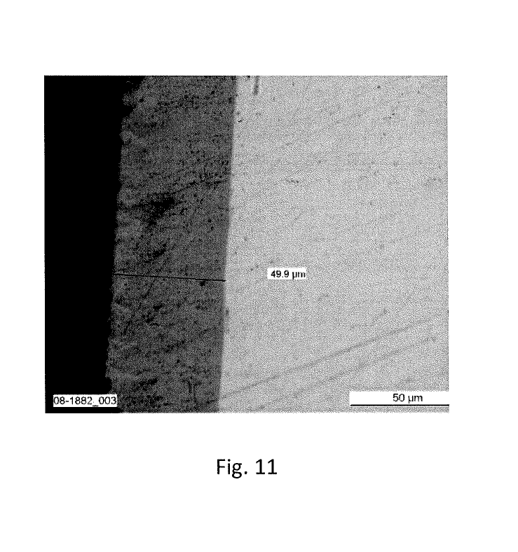

FIG. 11 shows a cross-sectional image of a stainless steel substrate with a 49.9 μm tantalum coating that was deposited at a temperature of 835° C. for 8 hours.

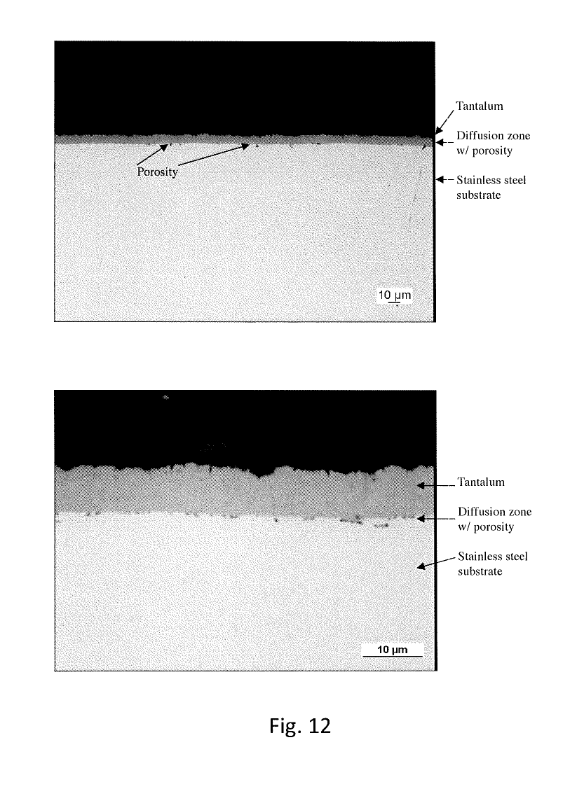

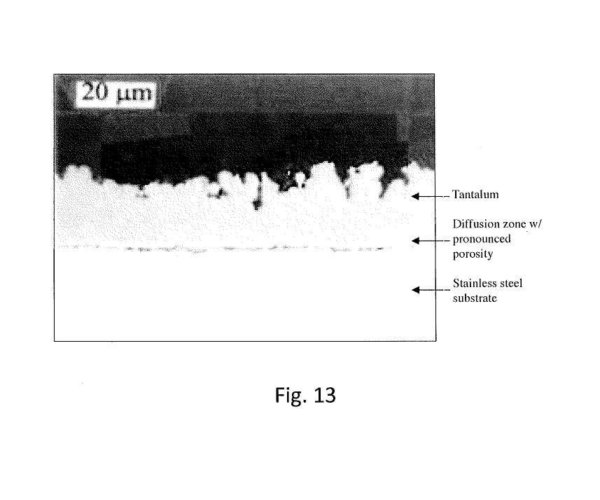

FIG. 12 shows two cross-sectional images of a stainless steel substrate with a 10 μm tantalum coating that was deposited at a temperature 900° C. for one (1) hour.

FIG. 13 shows a cross-sectional image of a stainless steel substrate with a 20 μm tantalum coating that was deposited at a temperature 950° C. for 142 minutes.

### DETAILED DESCRIPTION

FIG. 1 shows is a schematic view of an object (1) of the invention, where the object comprises the core element (2) having a surface, a corrosion resistant coating (4) covering at least part of the surface of the core element (2), where the corrosion resistant coating consists of at least 80% by weight of tantalum or preferably of a metal of the same group of metals as tantalum, like W, Nb, Mo, Ti, Hf. Between the core element (2) and the coating (4) is an interface, or alloying, section (3) ensuring a good adhesion of the coating (4).

The diffusion is controlled by the temperature, otherwise unfavourable diffusion parameters may result in Kirkendall porosity at the coating-base material interface, meaning that if the diffusion fluxes of the alloying elements from the core element (2) are different from the diffusion fluxes of the alloying elements from the coating (4), there will be a net flow of matter. Given that there is a net flow of matter there will be an equal and opposite net flow of vacancies, being missing atoms in a crystal structure, and forming pores or porosities.

FIG. 2 illustrates this general problem, especially being the case when the core element (2) is steel, or just an Ni containing element, where porosities (5), being empty pockets or vacuums, exists in the alloying layer (3) These porosities (5) give weaknesses in the adhesion of the coating layer (4) to the core element (2), because they are weak points where, when the coated object (1) is being subdued to mechanical deformations, possibly as part of the shaping/manufacturing of the object, or as part of the use of the object, cracks may appear in the coating layer at these weaknesses, thereby creating pinholes to the porosities.

Such an object (1) having a sufficient ductile corrosion resistant coating layer (4) to withstand mechanical deformations, is ensured by forming an alloying zone (3) between the core element (2) and the coating (4) that comprises especially the alloying elements Ni, Fe and Ta, but where the concentration by weight of Ni is nowhere higher than 20%, more preferably less than 15%, more preferably less than 10%. Material concentrations referred to herein are by weight unless otherwise indicated.

This interface or alloying zone (3) contains tantalum at an increasing concentration from the core element to the surface layer. The transition between the tantalum surface, or the coating, (4) and the interface, or alloying zone, (3), is defined by the depth where the content of tantalum is 90% by weight of the content of tantalum in the coating (4). The transition from the alloying zone (3) to the core element (2) is defined as the depth where the tantalum concentration is 10% by weight of the content in the coating (4). The alloying zone (3) is in general from 0.1 micrometers to 10 micrometers into the object, or more preferred from 0.3 to 2.0 micrometers.

Since the temperature is the predominant parameter used to control the diffusion of elements in the alloying zone, where the process temperatures would be in the range from 700° C. to 1200° C., a ‘cold process’ such as sputtering would not be suitable to form the desired alloying zone (3). Therefore, to apply the coating layer (4) of a corrosion resistant material to at least a part of the outer surface of the core element, a CVD process at a temperature between 700 and 1200° C. is preferred.

The coating layer is applied at a rate that ensures the formation of an alloying zone (3) between the core element (2) and the coating layer (4) having a thickness from where the concentration of said corrosion resistant material is 90% of the concentration in the coating layer, to where the concentration of said corrosion resistant material is 10% of the concentration in the coating layer, of at least 0.1 micrometers.

The process time typically is in the range of 1-20 hours, or more preferably 5-10 hours.

One critical factor to give the process temperature is the concentration of Ni in the core element (2), where, the more Ni, the lower temperature is needed, and the less Ni, the higher temperature is tolerable.

It has been found that keeping the CVD process temperature at equal to or less than 875° C. and keeping the diffusion layer thickness at equal to or less than 2 μm maintains the ductility of the tantalum/stainless steel interface such that both the stainless steel substrate and the tantalum coating layer can be mechanically deformed to form a coated object having a desired shape.

When a tantalum coating layer is deposited on an austenitic stainless steel substrate by a CVD process at temperatures at or below 875° C. and the diffusion zone thickness is kept below 2 μm, the entire resulting coated object, including an interface alloying zone, is sufficiently ductile to perform plastic deformation without delaminating, cracking or otherwise damaging the corrosion-resistant properties of the coated object. A good demonstration of the exceptional ductility of the tantalum coating diffusion layer stainless steel system is a combined indentation and U-bending test (r=5 mm) with the indented are on the outside of the bend not resulting in loss of corrosion resistance in hot concentrated hydrochloric acid (see http://www.tantaline.com/Ruggedness-Durability-485.aspx). The ductile properties of the resulting coated object also ensure thermal-shock resistance and unchanged fatigue strength.

When the tantalum coating layer is deposited at temperatures above 875° C., the diffusion of tantalum becomes more pronounced, thereby creating a thicker alloying zone. Also the mechanical properties of the resulting coated object change in part because of the thicker alloying zone, which creates higher stress levels during bending. Also, at higher temperatures (e.g., 950° C.-1000° C.), unfavourable diffusion parameters may result in Kirkendall porosity, which may cause cracks to the coating layer. The process temperature is the main driving parameter for thicker diffusion layers along with the process time. If a thick diffusion layer is obtained even at lower temperature the result is loss of ductility.

Temperatures below 700° C. is of little or no interest for manufacturing of industrial coatings since the deposition rate drops below 1 μm/hour meaning that the processing time required to produce a typical 20-50 μm layer would be impractically long.

### Examples

Coating a carbon steel substrate with up to 0.5% C at temperatures from 625 to 900° C. gives coatings that are similar to those on stainless steel, but where good adherence is more easily obtained. A coating deposited at 875° C. for 195 min revealed a 1-1.5 μm diffusion zone, or alloying zone, found visually on microscopical pictures.

FIGS. 3 and 4 are illustrations of a further aspect of the object (1) of the invention, where the object (1) is subdued to mechanical processing after the coating (4) has been applied to the core element (2).

FIG. 3A shows a core element (2) with some kind of protrusions (6A) at the surface, where a corrosion resistant surface coating (4) is deposited on at least a part of the surface of the core element (2), and where an alloy zone (3) is formed between the core element (2) and the coating (4). FIG. 3B shows that these protrusions (6A) have then been reshaped by some not further specified mechanical process.

An example is that structures are formed into the surface of the object (1) after the tantalum/refractory layer is deposited. This could e.g. be to shape flow channels in the surface for fuel cells. Therefore it is essential that the object has a dense and ductile surface, meaning that at least the surface layer (4) and the alloy layer (3) are ductile. FIG. 4A illustrates such an embodiment, where an object (1) is seen formed with a substantially flat surface. By any known means, channels (7), or other surface structures, are formed into the surface of the object (1) as seen in FIG. 4B.

For all of the objects of the illustrations in FIGS. 3 and 4, it is essential that the surface layer (4) and the alloy zone (3) are sufficiently ductile to absorb or withstand the forces from the mechanical processing, without cracking or otherwise loosing the corrosion resistance.

Objective test evidence shows that when a tantalum coating layer is deposited on a stainless steel substrate at a deposition temperature of 875° C. or less, the entire resulting coated object, including an interface alloying zone, is sufficiently ductile to perform plastic deformation without delaminating, cracking or otherwise damaging the corrosion-resistant properties of the coated object. Further, objective test evidence shows that when a tantalum coating layer is deposited on a stainless steel substrate at a deposition temperature of more than 875° C., the diffusion of tantalum becomes more pronounced, which creates an interface alloying zone that is thicker and more porous than when the tantalum coating layer is deposited on the stainless steel substrate at a deposition temperature of 875° C. or less.

FIG. 5 shows a chart summarizing the results of various test samples shown in FIGS. 6-10 having tantalum-coating layers deposited on substrates by a CVD process at various temperatures. FIG. 6 shows test samples having tantalum-coating layers deposited on substrates by a CVD process temperature of 700° C. FIG. 7 shows a test sample having tantalum-coating layer deposited on a substrate by a CVD process temperature of 750° C. FIG. 8 shows test samples having tantalum-coating layers deposited on substrates by a CVD process temperature of 835° C. FIG. 9 shows test samples having tantalum-coating layers deposited on substrates by a CVD process temperature of 900° C. FIG. 10 shows test samples having tantalum-coating layers deposited on substrates by a CVD process temperature of 925° C.

FIG. 11 shows a cross-sectional image of a stainless steel substrate with a 49.9 μm tantalum coating that was deposited at a temperature of 835° C. for 8 hours. The image of FIG. 11 was obtained using a light microscope. The dark section on the left is a plastic mold that was used to prepare the cross-section of the test object. The grey section in the middle is a 49.9 μm tantalum coating. The light grey section on the right is a stainless steel substrate. As is evident from FIG. 11, the interface alloying zone between the tantalum coating and the stainless steel substrate is barely visible and has uninterrupted contact between the tantalum coating layer and the stainless steel substrate.

FIG. 12 shows two cross-sectional images of a stainless steel substrate with a 10 μm tantalum coating that was deposited at a temperature 900° C. for one (1) hour. The top image is at a first magnification and the bottom image is at a second greater magnification. The images of FIG. 12 were obtained using a light microscope. In both images, the dark section on the top is a plastic mold that was used to prepare the cross-section of the test object. The grey section in the middle is a 10 μm tantalum coating. The light grey section on the bottom is a stainless steel substrate. As is evident from the images of FIG. 12, the interface alloying zone between the tantalum coating and the stainless steel substrate is clearly visible and shows some porosity.

The test object shown in FIG. 12 has a 10 μm tantalum coating. In order to grow a thicker tantalum coating, longer deposition time is required, which would result in an even thicker and more porous interface alloying zone than seen in the test object shown in FIG. 12.

Further, objective test evidence shows that when a 20 μm tantalum coating layer is deposited on a stainless steel substrate at a deposition temperature of 950° C. for 142 minutes, a thicker and more porous interface alloying zone is created than when a 10 μm tantalum coating layer is deposited on a stainless steel substrate at a deposition temperature of 900° C. for one (1) hour.

For example, FIG. 13 shows a cross-sectional image of a stainless steel substrate with a 20 μm tantalum coating that was deposited at a temperature 950° C. for 142 minutes. The image of FIG. 13 was obtained using a light microscope. The dark section on the top is a plastic mold that was used to prepare the cross-section of the test object. The grey section in the middle is a 20 μm tantalum coating. The light section on the bottom is a stainless steel substrate. As is evident from the image of FIG. 13, the interface alloying zone between the tantalum coating and the stainless steel substrate is clearly visible and shows pronounced porosity. The image of FIG. 13 also shows that the tantalum coating is almost completely detached from the stainless steel substrate and is retained only by narrow bridges of material and the physical interference of the coating and the substrate.

While the present invention has been illustrated and described with respect to a particular embodiment thereof, it should be appreciated by those of ordinary skill in the art that various modifications to this invention may be made without departing from the spirit and scope of the present.

What is claimed is:

1. A corrosion resistant object comprising:
a core element being made from a first base material and having an outer surface;
a coating layer comprising a concentration of at least 70% of a corrosion resistant material covering at least a part of the outer surface of the core element; and
an alloying zone between the core element and the coating layer, said alloying zone having a thickness of 0.3 μm to 2.0 μm and having a corrosion resistant material concentration gradient from 90% of the concentration of the corrosion resistant material in the coating layer to 10% of the concentration of the corrosion resistant material in the coating layer;
wherein the coating layer is deposited on the outer surface of the core element by a CVD process at temperatures between 700° C. and 875° C.

2. The object as in claim 1, wherein a concentration of Ni in the alloying zone is nowhere higher than 20%.

3. The object as in claim 1, wherein the corrosion resistant material is tantalum or a metal selected from the group consisting of W, Nb, Mo, Ti, and Hf.

4. The object as in claim 1, wherein the core element is an Ni-containing metal.

5. The object as in claim 1, wherein the core element is steel.

6. The object as in claim 1, wherein the core element is stainless steel or carbon steel or a mixture thereof.

7. The object as in claim 1, wherein the coating layer has a thickness of 5 μm-200 μm.

8. The object as in claim 4, wherein the deposition temperature is determined based on the concentration of Ni in the core element.

9. The object as in claim 1, where the mechanical modification is caused by one or more of impacts, blow, strike, grinding, rolling or drawing.

10. A corrosion resistant object comprising:
a core element being made from a first base material and having an outer surface;
a coating layer comprising a concentration of at least 70% of a corrosion resistant material covering at least a part of the outer surface of the core element; and
an alloying zone between the core element and the coating layer, said alloying zone having a thickness of less than 2.0 μm and having a corrosion resistant material concentration gradient from 90% of the concentration of the corrosion resistant material in the coating layer to 10% of the concentration of the corrosion resistant material in the coating layer;
wherein the coating layer is deposited on the outer surface of the core element by a CVD process at temperatures between 700° C. and 875° C.

11. The object as in claim 10, wherein a concentration of Ni in the alloying zone is nowhere higher than 20%.

12. The object as in claim 10, wherein the corrosion resistant material is tantalum or a metal selected from the group consisting of W, Nb, Mo, Ti, and Hf.

13. The object as in claim 10, wherein the core element is an Ni-containing metal.

14. The object as in claim 10, wherein the core element is steel.

15. The object as in claim 10, wherein the core element is stainless steel or carbon steel or a mixture thereof.

16. The object as in claim 10, wherein the coating layer has a thickness of 5 μm-200 μm.

17. The object as in claim 13, wherein the deposition temperature is determined based on the concentration of Ni in the core element.

18. The object as in claim 10, where the mechanical modification is caused by one or more of impacts, blow, strike, grinding, rolling or drawing.
